(19) United States
(12) Patent Application Publication
(10) Pub. No.: US 2005/0218484 A1
(43) Pub. Date: Oct. 6, 2005

(54) Wiring carrier design

(76) Inventor: Ruediger Uhlmann, Dresden (DE)

Correspondence Address: SLATER & MATSIL LLP, 17950 PRESTON ROAD, SUITE 1000, DALLAS, TX, 75252, US

(21) Appl. No.: 11/089,542

(22) Filed: Mar. 24, 2005

(30) Foreign Application Priority Data
Mar. 25, 2004 (DE) 10 2004 015 091.5

(51) Int. Cl. H01L 23/495

(52) U.S. Cl. 257/668

(57) ABSTRACT

The invention relates to a wiring carrier design for a planar wiring carrier for receiving a plurality of chips, on the chip side of which chips of identical type are arranged in matrix-like fashion, a long narrow bonding channel surrounded by a soldering resist layer being situated in the center of each chip receptacle, and the further region of the chip receptacle area being free of soldering resist, and the chips in each case being encapsulated with a molding material. The invention is based on the object of providing a wiring carrier design with which a uniform application of adhesive can be achieved using simple means. The object is achieved by virtue of the fact that additional supporting elements (9) made of soldering resist, or made of some other suitable material, are applied on the wiring carrier (1) at least in the region of narrow stencil webs (8) that are readily flexible during the printing operation.

This application claims priority to German Patent Application 10 2004 015 091.5, which was filed Mar. 25, 2004 and is incorporated herein by reference.

### TECHNICAL FIELD

The invention relates to a wiring carrier design for a planar wiring carrier for receiving a plurality of chips.

### BACKGROUND

Wiring carriers of this type comprise a carrier material, on the chip side of which a cured layer of a soldering resist has been applied essentially over the whole area. For fixing the chips, an adhesive layer is applied on the soldering resist on the envisaged mounting position of the chip. This may be effected by means of customary methods appertaining to printing technology, e.g., the stencil printing method. The adhesive is consequently cured, e.g., by means of a heat treatment process.

A stencil is used for the application of adhesive, which stencil finds a closed and plane bearing area on the soldering resist. As a result, the applied layer of adhesive has a thickness corresponding to the thickness of the stencil.

In order to achieve a better adhesion between the carrier material of the wiring carrier and the layer of adhesive and also an encapsulation material that is to be applied later, the soldering resist is applied only in the edge region of the matrix and all around the bonding channels.

This has the consequence, however, that a closed and plane bearing area is no longer available for all parts of the stencil. The resultant disadvantage is that, due to the forces acting during the printing operation, parts of the stencil are partly or else entirely pressed onto the carrier material. In this case, the parts of the stencil that are completely pressed on are particularly those that have a narrow configuration and are thus readily flexible and/or which are further away from the supporting soldering resist layer.

The thickness of the printed-on layer of adhesive is thus significantly thinner in these regions. The fact that the layer of adhesive thus has varying thickness overall adversely influences the quality of the adhesive connection of the chip on the wiring carrier. This leads to problems in particular in the case of particularly thin layers of adhesive because whole-area adhesive contact with the chip can then no longer be achieved with chip bonding. The consequence is adhesive strength and reliability problems.

### SUMMARY OF THE INVENTION

In one aspect, the invention provides a wiring carrier design on which a uniform application of adhesive can be achieved by simple means.

The preferred embodiment of the invention relates to a wiring carrier design for a planar wiring carrier for receiving a plurality of chips, on the chip side of which chips of identical type are arranged in matrix-like fashion, a long narrow bonding channel surrounded by a soldering resist layer being situated in the center of each chip receptacle, and the further region of the chip receptacle area being free of soldering resist, and the chips in each case being encapsulated with a molding material. Advantages can be achieved, in the case of a wiring carrier design of this type by virtue of the fact that additional supporting elements made of soldering resist, or made of some other suitable material, are applied on the wiring carrier at least in the region of narrow stencil webs that are readily flexible during the printing operation.

A significantly improved printing quality is achieved as a result of the invention, which leads to a more uniform distribution of the adhesive or the solder. What is more, considerably improved reliability of the contacts and thus of the yield is achieved.

The additional supporting elements are preferably formed as narrow contiguous areas.

In particular developments of the invention, the additional supporting elements are formed as narrow interrupted elements, which preferably have a uniform form and are arranged at periodic distances relative to one another.

A further refinement of the invention is characterized in that the additional supporting elements are arranged on the wiring carrier centrally with respect to the flexible webs, the arrangement in the sawing track between the chips being preferred.

### BRIEF DESCRIPTION OF THE DRAWINGS

The invention will be explained in more detail below using an exemplary embodiment. In the associated figures of the drawing:

FIG. 1 shows a wiring carrier according to the prior art;

FIG. 2 shows the wiring carrier according to FIG. 1 with a printing stencil laid thereon (prior art); and

FIG. 3 shows the wiring carrier with additional supporting area.

The following list of reference symbols can be used in conjunction with the figures:
1 Wiring carrier
2 Bonding channel
3 Soldering resist layer
4 Soldering resist layer
5 Opening in the printing stencil
6 Opening in the printing stencil
7 Printing stencil
8 Flexible web
9 Supporting area/supporting element

### DETAILED DESCRIPTION OF ILLUSTRATIVE EMBODIMENTS

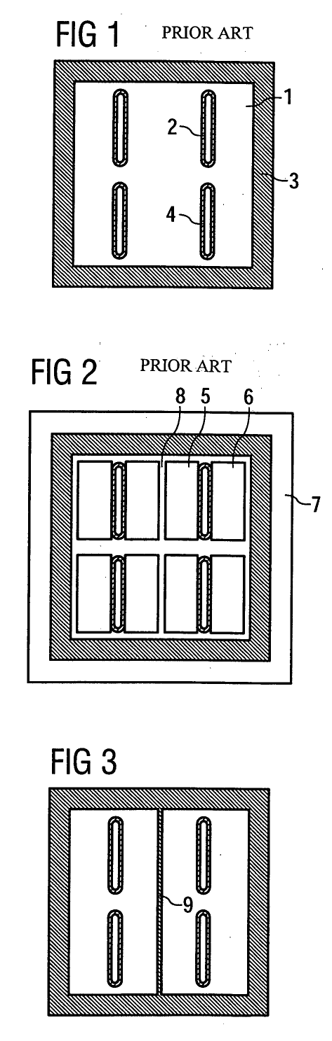

FIG. 1 shows a customary wiring carrier 1 according to the prior art, which is provided with bonding channels 2 and a soldering resist layer 4 around the bonding channels 2 and also a further soldering resist layer 3 on the edge of the wiring carrier 1.

FIG. 2 shows the same wiring carrier according to FIG. 1 with a printing stencil 7 laid thereon and the openings 6 thereof in the printing stencil 7 for the application of adhesive to the wiring carrier.

The opening 6 in the printing stencil 7 bears closely on the soldering resist on three sides (on the left, at the top and on the right in accordance with the drawing), the web in the stencil on the bottom side being wide and scarcely compliant. The layer of adhesive applied through the opening 6 in the printing stencil 7 thus has a uniform layer thickness corresponding to the sum of the thicknesses of stencil and soldering resist.

The opening 5 in the printing stencil bears closely on the soldering resist on two sides and, on the bottom side, the web in the stencil is wide and scarcely pliable. However, on the left-hand side, only a narrow and flexible web 8 is present in the printing stencil 7.

As a result, the layer of adhesive applied/printed on through the opening 5 has, towards its left-hand side in accordance with the drawing, a significantly smaller thickness, which corresponds there only to the thickness of the printing stencil 7.

FIG. 3 illustrates an additional supporting area 9 according to the invention, which is designed in the form of a long and very narrow area made of a soldering resist or some other suitable material. This narrow, supporting area 9 or supporting elements is or are arranged in the center of a separating sawing track below the narrow, readily flexible webs of the printing stencil 7. A separating sawing track is to be understood to mean a line along which the arrangement that has been completed by molding is divided into individual assemblies by sawing.

The result of the use of supporting areas 9 according to the invention is a significantly improved printing quality, which leads to a more uniform distribution of the adhesive or the solder. What is more, a considerably improved reliability of the contacts and thus of the yield is achieved.

1. A planar wiring carrier for receiving a plurality of chips, the carrier comprising:
a carrier substrate including a chip side on which a plurality of chips can be arranged in matrix-like fashion, each chip being arranged on a chip receptacle area of the carrier substrate;
a plurality of bonding channels, each bonding channel being situated in the center of a chip receptacle area;
a soldering resist layer formed on the carrier substrate surrounding each bonding channel such that other portions of the chip receptacle area are free of soldering resist; and
supporting elements formed on the carrier substrate between chip receptacle areas.

2. The carrier of claim 1, wherein the bonding channels comprise long narrow bonding channels.

3. The carrier of claim 1, wherein the supporting elements are formed at least in the region of narrow stencil webs that are readily flexible during a printing operation.

4. The carrier of claim 3, wherein the supporting elements are arranged on the carrier substrate centrally with respect to the flexible webs.

5. The carrier of claim 4, wherein the supporting elements are arranged along the sawing tracks between the chip receptacle areas.

6. The carrier of claim 1, wherein the supporting elements are made of soldering resist.

7. The carrier of claim 1, wherein the supporting elements are formed as narrow contiguous areas.

8. The carrier of claim 1, wherein the supporting elements are formed as narrow interrupted elements.

9. The carrier of claim 1, wherein a plurality of supporting elements are provided which have a uniform form.

10. The carrier of claim 9, wherein the supporting elements are arranged at periodic distances relative to one another.

11. The carrier of claim 1, wherein the supporting elements are arranged along the sawing tracks between the chip receptacle areas.
